(19) United States
(12) Patent Application Publication
(10) Pub. No.: US 2015/0184285 A1
(43) Pub. Date: Jul. 2, 2015

(54) SPUTTERING APPARATUS AND METHOD THEREOF

(71) Applicant: Samsung Display Co., LTD., Yongin-City (KR)

(72) Inventors: Takayuki FUKASAWA, Seoul (KR); Yeon-Keon MOON, Seoul (KR); Sang-woo SOHN, Yongin-si (KR); Sang-Won SHIN, Yongin-si (KR); Katsushi KISHIMOTO, Hwaseong-si (KR)

(21) Appl. No.: 14/558,521

(22) Filed: Dec. 2, 2014

(30) Foreign Application Priority Data
Dec. 30, 2013 (KR) 10-2013-0167286

(51) Int. Cl. C23C 14/35; H01J 37/34

(52) U.S. Cl. CPC C23C 14/352; C23C 14/35; H01J 37/3405; H01J 2237/332

(57) ABSTRACT

A sputtering apparatus includes a chamber, a plate disposed inside the chamber, a target unit including at least one targer facing the plate, a power supply unit coupled to the target, and a filter unit disposed between the substrate and the target. The filter unit includes at least one filter. A substrate is disposed on the plate. The filter unit may include a first filter and a second filter with the first filter disposed between the target and the second filter.

### CROSS-REFERENCE TO RELATED APPLICATION

This application claims priority to and the benefit of Korean Patent Application No. 10-2013-0167286, filed on Dec. 30, 2013, with the Korean Intellectual Property Office, the disclosure of which is incorporated herein in its entirety by reference.

### BACKGROUND

1. Field of the Invention

Embodiments of the present invention relate to a sputtering apparatus capable of achieving an effect of heat treatment while performing a sputtering process, and a sputtering method.

2. Description of Related Technology

Display devices include a plurality of pixels in an area defined by a black matrix or a pixel defining layer. Currently, there are displays such as a liquid crystal display (LCD), an organic light emitting diode (OLED) display, a plasma display panel (PDP), and an electrophoretic display (EPD) according to light emitting methods.

Recently, flexible displays, in which a display device is formed on a flexible substrate, have been developed and focused. Flexible displays are not only thinner and lighter but also flexible, so that they can be embodied in diverse forms. For this reason, flexible displays are considered to be the next generation technology in the field of display devices.

Thin film transistors which drive display devices are categorized into amorphous silicon (a-Si) transistors, polycrystalline silicon (poly-Si) transistors, and amorphous oxide semiconductor (AOS) transistors, according to the material which forms a semiconductor layer used for the thin film transistor.

The amorphous silicon (a-Si) may be suitably used for flexible displays in terms of being amorphous, but it is an unsuitable material for the flexible displays due to its disadvantages such as slow charge mobility and low stability. The polycrystalline silicon (poly-Si) is preferable in terms of fast charge mobility and high stability but is, on the other hand, not preferable due to its manufacturing process conditions such as a high temperature at which the poly-Si needs to be formed, which makes forming a poly-Si layer on a flexible substrate such as a plastic substrate difficult.

The amorphous oxide semiconductor (AOS) has an advantage of faster charge mobility than a-Si and a lower process temperature than poly-Si. For this reason, AOS can be applied to flexible displays.

However, in order to form high-quality oxide semiconductor thin films, annealing should be conducted at a temperature of 350° C. or higher, and thus it is difficult to form high-quality oxide semiconductor thin films on a flexible substrate such as a plastic substrate.

It is to be understood that this background of the technology section is intended to provide useful background for understanding the here disclosed technology and as such, the technology background section may include ideas, concepts or recognitions that were not part of what was known or appreciated by those skilled in the pertinent art prior to corresponding effective filing dates of subject matter disclosed herein.

### SUMMARY

Aspects of embodiments of the present invention are directed to a sputtering apparatus capable of forming a high-quality thin film without performing a high-temperature heat treatment, and a sputtering method.

According to an embodiment of the present invention, a sputtering apparatus may include: a chamber; a plate disposed inside the chamber, a target unit including at least one targer facing the plate; a power supply unit coupled to the target; and a filter unit disposed between the substrate and the target. The filter unit includes at least one filter. A substrate is disposed on the plate.

The filter unit has one pair of filters, and each filters are spaced apart having a predetermined distance in a horizontal direction.

The filter may include a first filter and a second filter, the first filter disposed between the target and the second filter.

The at least one filter may have any one shape of sphericalness, cylinder, or plate.

The filter may be capable of rotating about an axis parallel to a surface of the target, or the filter may be capable of moving along a direction parallel to a surface of the target.

The sputtering apparatus may further include a magnet on one side of the target.

The power supply unit may supply a voltage pulse having a duty ratio of about 30% to about 100%.

The voltage pulse may have a pulse width of about 30 ms to about 100 ms.

The sputtering apparatus may further include a heating unit facing the plate in the chamber, and the heating unit applies heat a surface of the substrate to be treated.

The heating unit may apply heat to the substrate surface after sputtering is complete.

The sputtering apparatus may further include a temperature regulating unit connected to the plate. The temperature regulating unit maintains a temperature of the substrate within a predetermined range.

The target unit may include a plate-shaped target and a side target disposed on an end portion of the plate-shaped target.

The side target may be arranged in a manner that a sputtering angle of the plate-shaped target, measured at a center of the plate-shaped target, is in the range of 10 degrees to 30 degrees.

Pressure in the chamber may be maintained in a range of 0.01 Pa to 1 Pa during sputtering.

A distance between the target and the substrate may be larger than a mean free path of a sputtered particle.

The distance between the target and the substrate may be about 70 mm to about 150 mm.

According to an embodiment of the present invention, a sputtering method utilizing a sputtering apparatus that includes a chamber, a plate disposed inside the chamber with a substrate placed on the plate, a target facing the plate, a power supply unit coupled to the target, and a filter disposed between the substrate and the target. The method includes disposing a target and a substrate inside the chamber in a manner that a distance between the target and the substrate is larger than a mean free path of a sputtered particle, maintaining inner pressure of the chamber in a range of 0.01 Pa to 1 Pa by injecting discharge gas after a vacuum state is achieved inside the chamber, and applying a voltage pulse to the target.

The sputtering method may further include heating a surface of the substrate with a heating unit after sputtering is completed.

The voltage pulse may have a duty ratio in a range of 30% to 100% and a pulse width of the voltage pulse in a range of 30 ms to 100 ms.

The sputtering method may further include arranging the filter to have a polar angle of about 10 degrees to about 30 degrees from a normal line perpendicular to the center of the target.

According to embodiments of the present invention, a sputtering apparatus may allow a sputtered particle to reach a substrate with high energy (high velocity), thereby forming a thin film and also achieving effects of heat treatment. Consequently, a high-quality thin film can be formed even in the absence of separate heat treatment.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1A is a schematic cross-sectional view illustrating a sputtering apparatus according to an embodiment of the present invention.

FIG. 1B is a schematic perspective view illustrating a sputtering apparatus according to an embodiment of the present invention.

FIG. 2A is a view illustrating a sputtering angle of a sputtered particle on a target surface.

FIG. 2B is a graph showing relative velocity according to a sputtering angle of a sputtered particle.

FIG. 3A is a cross-sectional view illustrating a substrate area affected by a sputtered particle.

FIG. 3B is a table showing simulation results of a substrate area whose temperature is increased according to a velocity at which a sputtered particle reaches a substrate and the increased temperature.

FIG. 4 is a schematic cross-sectional view illustrating a sputtering apparatus according to a first embodiment of the present invention.

FIG. 5 is a graph showing film density increasing with on-time of a plasma pulse.

FIG. 6 is a graph showing temperature according to a duty ratio of a plasma pulse.

FIG. 7 is a schematic cross-sectional view illustrating a sputtering apparatus according to a second embodiment of the present invention.

FIG. 8 is a schematic cross-sectional view illustrating a sputtering apparatus according to a third embodiment of the present invention.

FIG. 9 is a schematic cross-sectional view illustrating a sputtering apparatus according to a fourth embodiment of the present invention.

FIG. 10 is a schematic cross-sectional view illustrating a sputtering apparatus according to a fifth embodiment of the present invention.

FIG. 11 is a schematic cross-sectional view illustrating a sputtering apparatus according to a sixth embodiment of the present invention.

FIG. 12 is a schematic cross-sectional view illustrating a sputtering apparatus according to a seventh embodiment of the present invention.

### DETAILED DESCRIPTION

Hereinafter, embodiments of the present invention are described with reference to the accompanying drawings.

Example embodiments of the present invention are illustrated in the accompanying drawings and described in the specification. The scope of the present invention is not limited to the example embodiments and should be construed as including all potential changes, equivalents, and substitutions to the example embodiments.

In the specification, when a first element is referred to as being “connected” to a second element, the first element may be directly connected to the second element or indirectly connected to the second element with one or more intervening elements interposed therebetween. The terms “comprises,” “comprising,” “includes,” and/or “including,” when used in this specification, may specify the presence of stated features, integers, steps, operations, elements, and/or components, but do not preclude the presence or addition of one or more other features, integers, steps, operations, elements, and/or components.

Although the terms “first,” “second,” and “third” and the like may be used herein to describe various elements, these elements should not be limited by these terms. These terms may be used to distinguish one element from another element. Thus, “a first element” could be termed “a second element” or “a third element,” and “a second element” and “a third element” can be termed likewise without departing from the teachings herein. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-type (or first-set),” “second-type (or second-set),” etc., respectively.

Like reference numerals may refer to like elements in the specification.

Embodiments of the present invention relate to a sputtering apparatus for forming a thin film on a substrate.

A substrate mentioned in the specification may refer to a display substrate of a liquid crystal display (LCD), an organic light emitting diode (OLED) display, a plasma display panel (PDP), or an electrophoretic display (EPD), a substrate for solar cells, or a semiconductor wafer substrate.

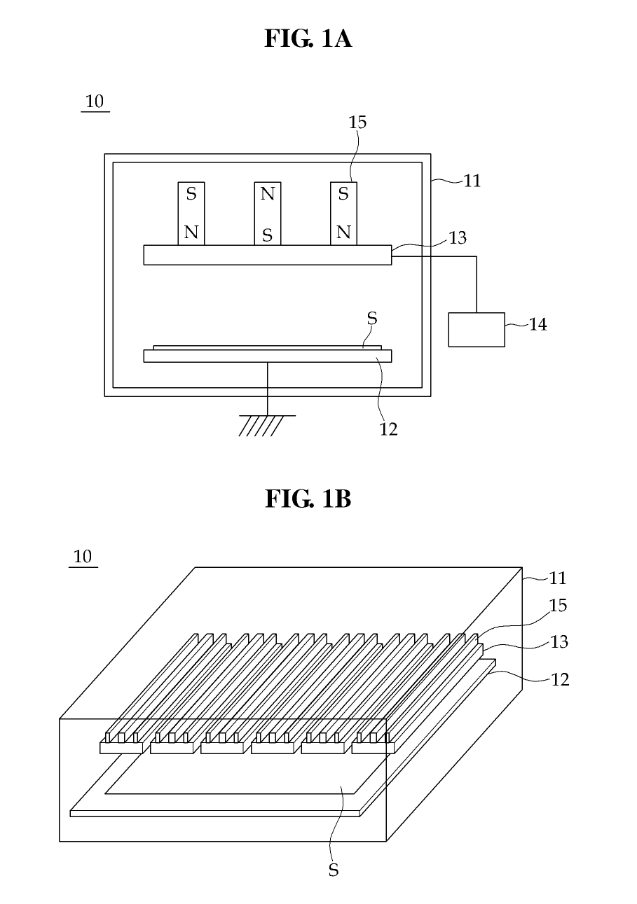

FIG. 1A is a schematic cross-sectional view illustrating a sputtering apparatus 10 according to an embodiment of the present invention. FIG. 1B is a schematic perspective view illustrating a sputtering apparatus 10 according to an embodiment of the present invention. The sputtering apparatus 10 may have one or more features that may be analogous to or substantially identical to one or more features of a conventional sputtering apparatus.

Referring to FIGS. 1A and 1B, the sputtering apparatus 10 includes a chamber 11, a plate 12 disposed inside the chamber 11, the plate 12 on which a substrate S to be treated is placed, a target 13 that is disposed to face the plate 12 and is made of a thin film-forming material, a power supply unit 14 configured to supply power to the target 13, and at least one pair of magnets 15 disposed on one side of the target 13 and producing a magnetic field.

A sputtering method utilizing the sputtering apparatus 10 will be described below.

First, a vacuum state is achieved inside the chamber 11 and discharge gas such as argon (Ar) is then injected into the chamber 11. Thereafter, power is applied to the target 13 so that an electric field is applied to the discharge gas, and electric discharge begins. Gas molecules ionized due to the electric discharge, namely ions, are accelerated towards the target 13 by the electric field.

Collisions eventually occur between the accelerated ions or neutral particles and the target 13, thereby sputtering a target material present on a surface of the target 13. In the specification, the sputtered target material is called a “sputtered particle.” When the sputtered particle reaches the substrate S, a thin film is formed on a surface of the substrate S. In this case, the sputtered particle is influenced by a magnetic field produced by the magnets 15, thereby improving efficiency in forming the thin film.

Meanwhile, in order to form a high-quality thin film, after sputtering, annealing is performed at a temperature of 200° C. or higher. However, such high temperature is not a suitable condition to be used with a flexible substrate such as a plastic substrate.

Hereinafter, a sputtering apparatus capable of forming a high-quality thin film without separate heat treatment according to embodiments of the present invention is described with reference to the accompanying drawings.

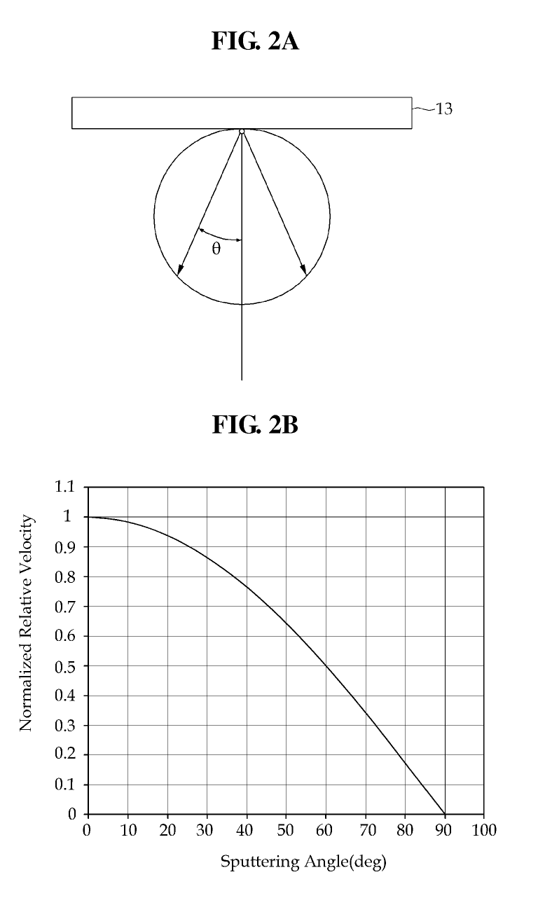

FIG. 2A is a view illustrating a sputtering angle of a sputtered particle on a target surface. FIG. 2B is a graph showing relative velocity according to a sputtering angle of a sputtered particle.

In the specification, a sputtering angle of a sputtered particle is defined with respect to a normal line direction of a target 13 as shown in FIG. 2A. The normal line is a line perpendicular to a surface of the target, which faces the substrate as shown in FIG. 2A, directly connecting the surface of the target to a surface of the substrate. Referring to FIG. 2A, the sputtered particle obeys the law of cosines, and thus as the sputtering angle θ of the sputtered particle becomes narrower, the sputtering occurs at higher velocity. In contrast, as the sputtering angle θ of the sputtered particle becomes wider, the sputtering occurs at lower velocity.

FIG. 2B is a graph showing relative velocity according to a sputtering angle of a sputtered particle. That is, the graph of FIG. 2B shows normalized relative velocity in accordance with changes of the sputtering angle based on the assumption that the sputtered particle has a velocity of 1 when the sputtering angle is 0 degree.

Referring to FIG. 2B, it can be known that when the sputtering angle is ±10 degrees, the velocity of the sputtered particle is reduced by about 2% compared to the maximum velocity. It can also be known that when the sputtering angle is ±60 degrees, the velocity of the sputtered particle is reduced by about 50% compared to the maximum velocity. Thus, as the sputtered particle has a narrower sputtering angle θ, the sputtering occurs at higher velocity (or speed). In contrast, as the sputtered particle has a wider sputtering angle θ, the sputtering occurs at lower velocity (or speed).

According to the Thornton's structure zone model (J. A. Thornton: Ann. Rev. Mater. Sci., 7, 1977), when L/λ (L: distance between a target and a substrate; X: mean free path) is less than 1, that is when collisions between the sputtered particle and the accelerated ions are not dominant, the thin film layer having a high density and a smoother surface morphology may be formed.

Therefore, the sputtering apparatus according to one embodiment maintains the distance between the target and the substrate to be shorter than the mean free path of the sputtered particle.

Further, the sputtering apparatus according to one embodiment maintains the temperature of a thin film formed on the substrate to be T/Tₘ=0.1˜0.5 (T: surface temperature of the thin film; Tₘ: melting point of the target particle).

For instance, when the pressure inside the chamber is 1 Pa or higher, and the distance between the target and the substrate is 10 mm or less, the initial energy(or temperature) of the sputtered particle generally has a value of about 2 eV to about 10 eV (20000K to 100000K) in the normal line direction (θ=0) of the target. However, due to collisions with ions or neutral particles, when the sputtered particle arrives at the substrate, the energy(or temperature) is reduced to a value of about 0.2 eV to about 0.5 eV (2000K to 5000K).

In the case where the pressure inside the chamber is reduced to 1 Pa or lower and the distance between the target and the substrate is increased to 10 mm or more, the mean free path of the sputtered particle increases, and thus the sputtered particle may arrive at the substrate while maintaining the initial energy(or temperature).

Therefore, when sputtering is performed, the target is desirably spaced about 70 mm to about 150 mm apart from the substrate in order to achieve annealing effects on a thin film.

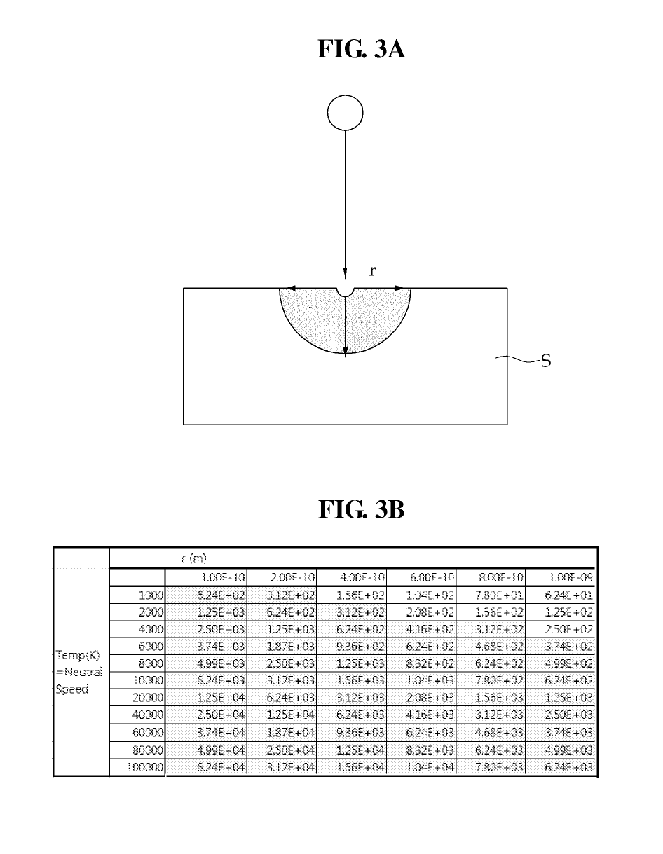

FIG. 3A is a cross-sectional view illustrating a substrate area affected by a sputtered particle.

FIG. 3B is a table showing simulation results of a substrate area whose temperature is increased according to a velocity at which a sputtered particle reaches a substrate and the increased temperature. In FIG. 3B, the target material used for the simulation is indium oxide (In₂O₃).

Referring to FIGS. 3A and 3B, when the velocity (Temp, Neutral Speed) at which a sputtered In₂O₃ particle reaches the substrate is 6000K, the substrate temperature is increased by about 374K within a radius r of 1 nm (10 Å). Further, when the velocity (Temp, Neutral Speed) at which the sputtered In₂O₃ particle reaches the substrate is 2000K, the substrate temperature is further increased by about 312K within a radius r of 0.4 nm (4 Å) referring to the table shown in FIG. 3B.

Assuming annealing effects are generally achieved when the temperature increases by 300K or more, the annealing may be applied to a substrate area that is within a radius r of 1 nm (10 Å) in the substrate (shown in FIG. 3A) if the sputtered In₂O₃ particle reaches the substrate at a temperature of 6000K, and the annealing may be applied to a substrate area that is within a radius r of 0.4 nm (4 Å) in the substrate if the sputtered In₂O₃ particle reaches the substrate at a temperature of 2000K.

Such annealing effects occurs only in a thin layer in a range of 1 nm to 10 nm, and since the temperature decreases rapidly due to thermal diffusion, the temperature of the entire substrate may not increase. Further, if a plurality of sputter particles are made incident onto the substrate, the annealing effects may be obtained while the sputtering is performed.

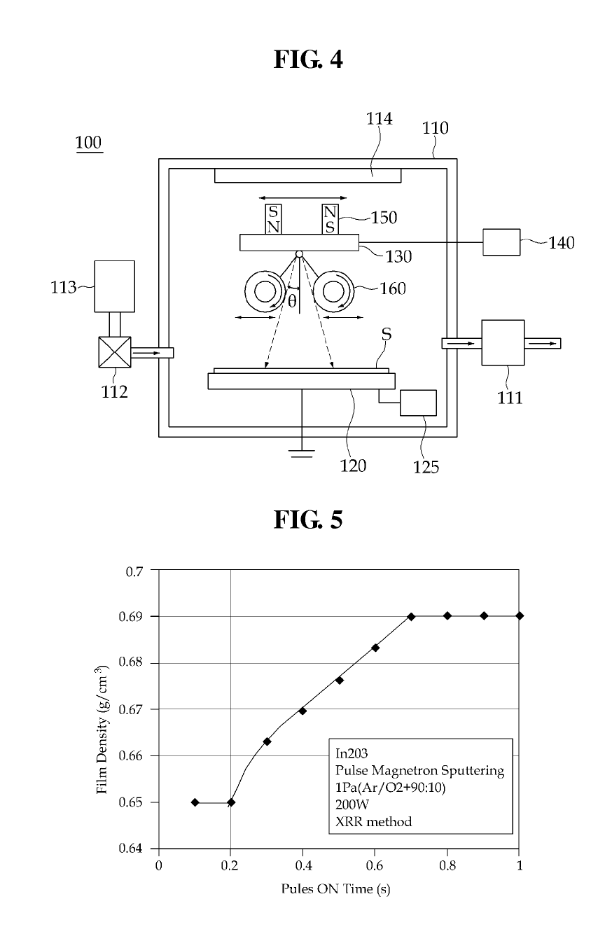

FIG. 4 is a schematic cross-sectional view illustrating a sputtering apparatus according to a first embodiment of the present invention.

Referring to FIG. 4, a sputtering apparatus 100 according to the first embodiment includes a chamber 110, a plate 120 disposed inside the chamber 110, at least one target 130 that faces the plate 120 and is made of a thin film-forming material, a power supply unit 140 to supply power to the target 130, at least one pair of magnets 150 that is disposed on one side of the target 130 and produces a magnetic field, and at least one pair of filters 160 disposed between the plate 120 and the target 130. A substrate S is placed on the plate 120.

The sputtering apparatus 100 according to the first embodiment may further include a temperature regulating unit 125 configured to keep the substrate S placed on the plate 120 at a constant temperature.

The sputtering apparatus 100 may further include a vacuum pump 111 to create a vacuum state within the chamber 110, a mass flow controller (MFC) 112 to inject discharge gas such as argon (Ar) into the chamber 110, and a gas tank 113 to store the discharge gas.

The sputtering apparatus 100 may further include a heating unit 114 to apply heat to a surface of the substrate S.

The discharge gas injected into the chamber 110 may include, for example, a mixture of a noble gas such as argon (Ar) and nitrogen (N₂), oxygen (O₂), and nitrous oxide (N₂O).

It is desirable that the discharge gas further includes at least one selected from elements in groups V, VI, VII, and VIII of the periodic table. Among the discharge gases, argon (Ar) is metastable, and nitrogen (N₂) or nitrous oxide (N₂O) has a plurality of vibrational energy levels, and thus thermal energy can be produced on a substrate surface. Therefore, the annealing effects achieved by the collisions of a target with neutral particles may also result from the discharge gas on the substrate surface.

When sputtering is performed by using the sputtering apparatus 100 according to the first embodiment, the pressure in a range of 0.01 Pa to 1 Pa may be maintained in the space inside the chamber 110.

In the case where heat treatment is not sufficiently applied to the outermost surface of a thin film on the substrate S during sputtering, the heating unit 114 may further apply heat treatment to the outermost surface of the thin film. A lamp or laser may be utilized as the heating unit 114, and only the outermost surface of the thin film may be heat-treated within a short time by using the heating unit 114.

Referring to FIG. 5, it can be known that a film density of In₂O₃ film formed on the substrate S increases as on-time of a plasma pulse increases to about 0.7 second. Herein, the plasma pulse is a plasma state driven by voltage pulse applied to the target 130 from the power supply unit 140. Herein, the pulse on-time of a plasma pulse is a time period during which the plasma pulse is applied. In other words, when a plasma pulse is continuously in a turned-on state, annealing effects by sputtering start to occur from the pulse on-time of 0.2 second and thereafter, and are saturated in the pulse on-time of about 0.7 second. In the case where continuous sputtering is performed, a thin film layer formed later may not be annealed at the pulse on-time of 1 second or less.

The heating unit 114 applies heat to the thin film layer on the substrate by lamp heating, laser heating, or line plasma process for about 1 second after the sputtering is completed so as to anneal the thin film layer formed on the substrate S at the later stage of the sputtering process.

Meanwhile, the temperature regulating unit 125 may be coupled to the plate 120. The temperature regulating unit 125 is configured to keep the substrate S placed on the plate 120 at a constant temperature, thereby preventing the substrate S from being damaged.

The target 130 is disposed to face the plate 120 and acts as a sputter source in a sputtering process. The target 130 is made of various materials such as metals, ceramics, or polymers, and may be made of materials in powder form as well as solid materials.

The target 130 may be made of a thin film-forming material, and in the first embodiment, the target 130 is made of an oxide semiconductor-forming material. Examples of the oxide semiconductor-forming material may include at least one selected from indium oxide (In₂O₃), amorphous-indium-gallium-zinc oxide (a-IGZO), zinc oxide (ZnO), indium zinc oxide (IZO), tin indium zinc oxide (TIZO), and zinc tin oxide (ZTO).

The target 130 may have a variety of shapes such as planar, circular, oval, cylindrical, and other shape. Desirable shapes of the target 130 according to the first embodiment will be described below in more detail.

The power supply unit 140 applies power (e.g., direct current (DC), alternating current (AC), DC pulse, AC pulse, etc.) to the target 130. The power supply unit 140 may further include a circuit such as a matching circuit if necessary. In the case where the power supply unit 140 applies the direct current (DC) to the target 130, a negative (−) voltage is generally applied to the target 130.

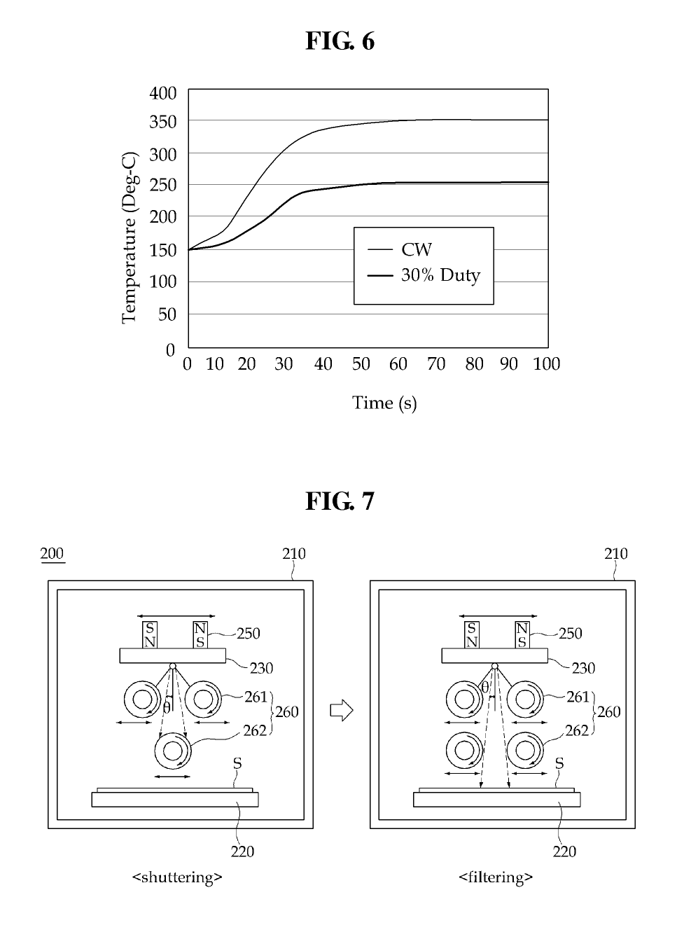

The power supply unit 140 may adjust a duty ratio (%) of a plasma pulse so as to control the initial energy(or temperature) of the sputtered particle. Referring to FIG. 6, when the duty ratio is 100% (CW in FIG. 6), the substrate surface on which a layer is formed has a saturation temperature of 350° C., and when the duty ratio is 30% (turned on for 30% of the time and turned off for 70% of the time), the substrate surface has a saturation temperature of about 250° C. Therefore, the plasma pulse is desirably has a duty ratio in a range of 25% to 100%.

Further, the plasma pulse is desirably has a pulse period (or pulse width) in a range of 30 ms to 100 ms in consideration of heat transferring velocity of the substrate surface.

At least one magnet 150 may be disposed on one side of the target 130, e.g., on the surface of the target 130 opposite to the surface facing the substrate S. The magnets 150 may include a first loop-shaped magnet and a second magnet disposed on a central portion of the first magnet so as to form a uniform plasma without bias. Hereinafter, only a pair of magnets 150 are illustrated in drawings and are described below for brevity of description.

The magnet 150 produces magnetic lines of force (magnetic field), and thus it can influence the sputtered particle reaching the substrate S, thereby improving efficiency in forming a thin film on the substrate S. A sputtering apparatus including the magnet 150 is particularly called a magnetron sputtering device. Thus, the sputtering apparatus according to the first embodiment may be the magnetron sputtering device, but embodiments of the present invention are not limited thereto.

The filter 160 may trap a low-energy particle among particles that are departing from the target 130, and may allow a high-energy particle only to reach the substrate.

The fastest particle is emitted in the normal line direction of the target 130 because the particle emitted from the target 130 obeys the law of cosines. That is, the filter 160 induces only a high-speed sputtered particle to the substrate S and filters out a low-speed sputtered particle.

Thus, when the high-speed sputtered particle collides with the substrate S, due to heat generated by the collision, the effect of applying heat treatment to a thin film surface is achieved. That is, a thin film having high density and high charge mobility may be formed.

An area on which the heat treatment effect is exhibited by the collision falls within a very narrow scope of the outermost surface of the substrate S, and since thermal diffusion causes rapid reduction in temperature, the temperature of the entire substrate may not increase. The substrate S may be maintained at a predetermined temperature by using the temperature regulating unit 125 provided to the plate 120. Accordingly, even when the substrate S is made of a material such as plastic or PET in addition to glass, there is no damage that is likely to occur due to the annealing effect.

At least one pair of filters 160 may be provided. The pair of filters 160 has a space therebetween so that each of the filters 160 has a polar angle of ±30 degrees or less, or preferably ±20 degrees or less with a normal line perpendicular to the surface of the target 130 at the center of the surface. More desirably, the pair of filters 160 may be disposed to have a space therebetween so that each of the filters 160 has a polar angle of ±11 degrees or less with the normal line perpendicular to the surface of the target 130 at center of the surface. The filter 160 may be any one of a sphericalness type, a cylindrical type, or a plate type.

It is desirable to make surfaces of the filters 160 with the same material as the target 130. The filter 160 is rotatable, thereby trapping a low-speed sputtered particle emitted from the target 130 on the entire surface of the filter 160 and reusing the low-speed sputtered particle.

Further, the filters 160 may move in a horizontal direction, which is parallel to the surface of the substrate S as marked with double headed arrows in FIG. 4 while spinning (rotating) by themselves. The magnets 150 may move in this horizontal direction. The motion of the filters 160 is synchronized with the motion of the magnets 150. If the target 130 moves along a direction during the sputtering process, the filters 160 may move in the same direction together with the target 130.

The filter 160 may be coupled to a heating means (not shown).

In the sputtering apparatus 100 according to the first embodiment, the filter 160 may be rotatable and have a cylindrical shape. As described above, in the case of the rotatable filter 160, the low-speed sputtered particle, which is filtered out by the filter 160, may be prevented from being accumulated in one area and deposited.

The plate 120, the target 130, the magnet 150, and the filter 160 may be coupled to a moving apparatus (not shown) enabling vertical or horizontal movement in the chamber 110. In the case where the plate 120, the target 130, the magnet 150, and the filter 160 move horizontally at the same velocity during sputtering, high efficiency in thin film formation may be attained.

Hereinafter, a sputtering apparatus according to another embodiment is described in detail. Descriptions for a sputtering apparatus according to another embodiment, which is identical or analogous to the sputtering apparatus 100 according to the first embodiment, may not be repeated below.

FIG. 7 is a schematic cross-sectional view illustrating a sputtering apparatus according to a second embodiment of the present invention.

Referring to FIG. 7, the sputtering apparatus 200 according to the second embodiment includes a chamber 210, a plate 220 disposed inside the chamber 210, at least one target 230 that faces the plate 220 and is made of a thin film-forming material, at least one pair of magnets 250 that is disposed on one side of the target 230 and produces a magnetic field, and at least one filter unit 260 disposed between the plate 220 and the target 230. A substrate S is placed on the plate 220. The filter unit 260 may include a first filter 261 and a second filter 262 in two stages. The first and second filters 261 and 262 may move horizontally (parallel to the surface of the substrate) by a moving apparatus (not shown). Herein, the two stages of the filters mean two layers or levels of the filter arrangement. As shown in FIG. 7, the first filter 261 is positioned above the second filter 262 in a space between the target 230 and the substrate S. It may be described as that the first filter 261 is disposed on a first stage, and the second filter 262 is disposed on a second stage. The first stage is positioned closer to the target 230 than the first stage, and the second stage is positioned closer to the substrate S than the first stage.

In the case of a general sputtering apparatus, pre-sputtering is performed in an initial step when discharge starts. The pre-sputtering is a process performed to, for example, remove oxides or other impurities such as dirt preferentially from a target surface before an actual thin film is deposited. In this case, a shutter is separately provided between a target and a substrate so as to prevent a target particle mixed with impurities from reaching the substrate. A conventional sputtering apparatus for a large-size substrate does not include the shutter.

The sputtering apparatus 200 according to the second embodiment includes the filter unit 260 including the first and second filters 261 and 262 capable of moving horizontally, and a moving velocity of each filter is adjusted, thereby allowing the filter unit 260 to act as the shutter at the start of the discharge.

Referring to FIG. 7, when the first-stage filter 261 and the second-stage filter 262 move out of phase with each other (“shuttering” in the left figure of FIG. 7), the filter unit 260 may serve as a shutter that blocks all particles. When the first-stage filter 261 and the second-stage filter 262 move in phase with each other (“filtering” in the right figure of FIG. 7), both filters 261 and 262 of the filter unit 260 may serve to filter out low-speed particles only.

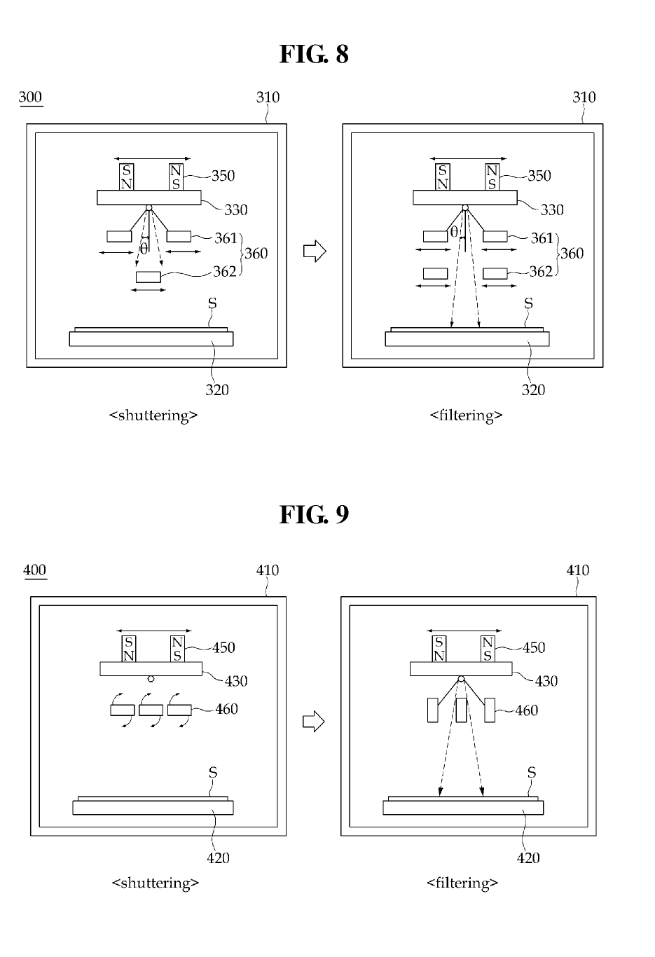

FIG. 8 is a schematic cross-sectional view illustrating a sputtering apparatus according to a third embodiment of the present invention.

Referring to FIG. 8, the sputtering apparatus 300 according to the third embodiment includes a chamber 310, a plate 320 disposed inside the chamber 310, at least one target 330 that faces the plate 320 and is made of a thin film-forming material, at least one pair of magnets 350 that is disposed on one side of the target 330 and produces a magnetic field, and at least one filter unit 360 disposed between the plate 320 and the target 330. A substrate S is placed on the plate 220. The filter unit 360 may include plate-shaped filters. The filter unit 360 may be provided in one stage or in two stages. That is, the filter unit 360 may include a first filter 361 and a second filter 362 disposed below the first filter 361 as shown in FIG. 8, and each of the first and second filters 361 and 362 may move horizontally (parallel to the surface of the substrate S) by a moving apparatus (not shown).

Further, when the first filter 361 and the second filter 362 move out of phase with each other (“shuttering” in the left figure of FIG. 8), the filter unit 360 may serve as a shutter that blocks all particles, whereas when the first-stage filter 361 and the second-stage filter 362 move in phase with each other (“filtering” in the right figure of FIG. 8), the filter unit 360 may serve to filter out low-speed particles only.

FIG. 9 is a schematic cross-sectional view illustrating a sputtering apparatus according to a fourth embodiment of the present invention.

Referring to FIG. 9, the sputtering apparatus 400 according to the fourth embodiment includes a chamber 410, a plate 420 disposed inside the chamber 410, at least one target 430 that faces the plate 420 and is made of a thin film-forming material, at least one pair of magnets 450 that is disposed on one side of the target 430 and produces a magnetic field, and at least one filter unit 460 disposed between the plate 420 and the target 430. A substrate S is placed on the plate 420. The filter 460 may be a plate-shaped filter. The filter 460 is provided in one stage, and may rotate to serve as a shutter (“shuttering” in the left figure of FIG. 9), and to serve as a filter (“filtering” in the right figure of FIG. 9). Even though the filter 460 is provided in only one stage, the filter 460 works as a shutter and as a filter based on the rotation state.

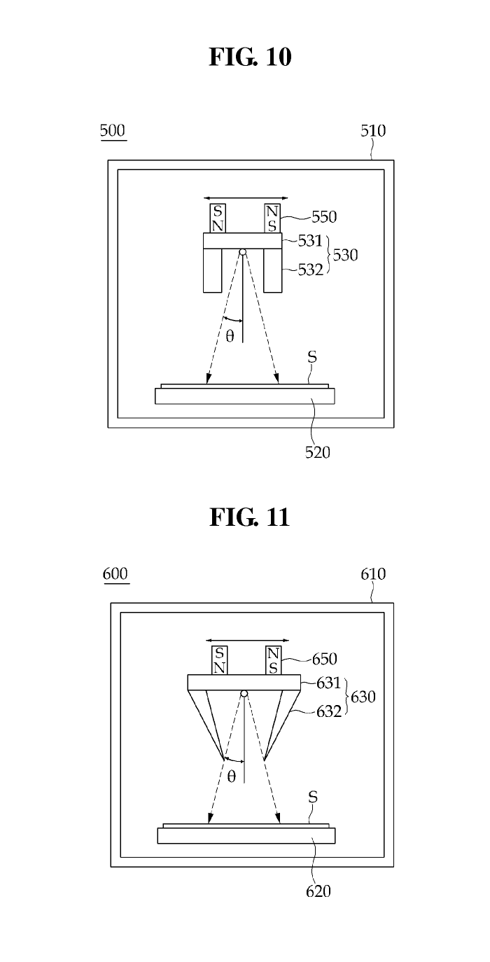

FIG. 10 is a schematic cross-sectional view illustrating a sputtering apparatus according to a fifth embodiment of the present invention.

Referring to FIG. 10, the sputtering apparatus 500 according to the fifth embodiment includes a chamber 510, a plate 520 disposed inside the chamber 510, at least one target unit 530 that faces the plate 520, and at least one pair of magnets 550 that is disposed on one side of the target unit 530 and produces a magnetic field. A substrate S is placed on the plate 520. The sputtering apparatus 500 may include the target unit 530 having a form that filters out low-speed particles and emits only high-speed particles. In detail, according to the fifth embodiment, the target unit 530 may include an upper target (first target) 531 and a side target (second target) 532 that is disposed on both end portions of the upper target 531 and protrudes towards the substrate S from a surface of the upper target 531. In this case, the sputtering angle θ of the upper target, when measured at a center of the upper target, is restricted by the side targets 532 in a range of 10 degrees to 30 degrees from the center of the upper target 531.

FIG. 11 is a schematic cross-sectional view illustrating a sputtering apparatus according to a sixth embodiment of the present invention.

Referring to FIG. 11, the sputtering apparatus 600 according to the sixth embodiment includes a chamber 610, a plate 620 disposed inside the chamber 610, at least one target unit 630 that faces the plate 620, and at least one pair of magnets 650 that is disposed on one side of the target unit 630 and produces a magnetic field. A substrate S is placed on the plate 620. The sputtering apparatus 600 may include the target unit 630 that includes a generally plate-shaped upper target (first target) 631 and a side target (second target) 632 having a shape of triangular prism. The side target 632 is disposed on both end portions of the upper target 631 and a tip of the triangular prism of the side target 632 protrudes towards the substrate S from a surface of the upper target 631 while the base of the triangular prism is disposed on the surface of the upper target 631.

In this case, the tip of the triangular prism of the side target 632 may bend towards the normal line formed at the center of the upper target 631, and therefore, the sputtering angle θ of this embodiment, as shown in FIG. 11, may be smaller than the sputtering angle shown in FIG. 10. In such a case, low-speed particles, which are filtered out by the side target 632, may be reused when sputtering is performed, and thus the lifetime of the target of the sixth embodiment (FIG. 11) may be longer than the lifetime of the target of the fifth embodiment (FIG. 10).

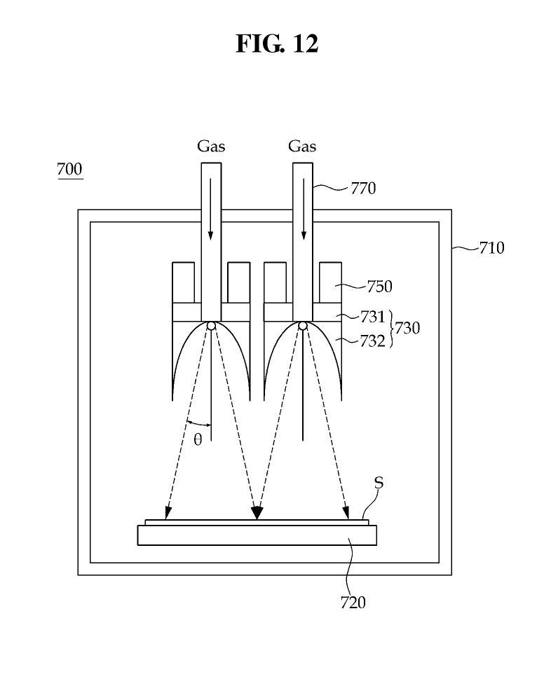

FIG. 12 is a schematic cross-sectional view illustrating a sputtering apparatus according to a seventh embodiment of the present invention.

Referring to FIG. 12, the sputtering apparatus 700 according to the seventh embodiment includes a chamber 710, a plate 720 disposed inside the chamber 710, at least one target unit 730 that faces the plate 720, and at least one pair of magnets 750 that is disposed on one side of the target unit 730 and produces a magnetic field. A substrate S is placed on the plate 720. The sputtering apparatus 700 may include the target unit 730, into which a mixture of a noble gas such as argon (Ar) and nitrogen (N₂), oxygen (O₂), and nitrous oxide (N₂O) is injected through a channel 770 disposed in a central portion of the target unit 730. Because of the injected gas, sputter particles may be accelerated to high velocity in the target.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims, and equivalents thereof.

What is claimed is:

1. A sputtering apparatus, comprising:
a chamber;
a plate disposed inside the chamber, a substrate being placed on the plate;
a target unit including at least one target facing the plate;
a power supply unit coupled to the target; and
a filter unit disposed between the substrate and the target, the filter unit including at least one filter.

2. The sputtering apparatus according to claim 1, wherein the filter unit has one pair of filters, and each filters are spaced apart having a predetermined distance in a horizontal direction.

3. The sputtering apparatus according to claim 1, wherein the filter unit comprises a first filter and a second filter, the first filter disposed between the target and the second filter.

4. The sputtering apparatus according to claim 1, wherein the at least one filter of the filter unit has any one shape of sphericalness, cylinder, or plate.

5. The sputtering apparatus according to claim 1, wherein the filter is capable of rotating about an axis parallel to a surface of the target, or the filter is capable of moving along a direction parallel to a surface of the target.

6. The sputtering apparatus according to claim 1, further comprising a magnet on one side of the target.

7. The sputtering apparatus according to claim 1, wherein the power supply unit supplies a voltage pulse having a duty ratio of about 30% to about 100%.

8. The sputtering apparatus according to claim 7, wherein the voltage pulse has a pulse width in a range of 30 ms to 100 ms.

9. The sputtering apparatus according to claim 1, further comprising a heating unit facing the plate in the chamber, the heating unit applying heat to a surface of the substrate.

10. The sputtering apparatus according to claim 9, wherein the heating unit heats the substrate surface after sputtering is completed.

11. The sputtering apparatus according to claim 1, further comprising a temperature regulating unit connected to the plate, the temperature regulating unit maintaining a temperature of the substrate within a predetermined range.

12. The sputtering apparatus according to claim 1, wherein the target unit comprises a plate-shaped target and a side target disposed on an end portion of the plate-shaped target.

13. The sputtering apparatus according to claim 12, wherein the side target is arranged in a manner that a sputtering angle of the plate-shaped target at a center of the plate-shaped target is in the range of 10 degrees to 30 degrees.

14. The sputtering apparatus according to claim 1, wherein the chamber is maintained at a pressure in a range of 0.01 Pa to 1 Pa during sputtering.

15. The sputtering apparatus according to claim 1, wherein a distance between the target and the substrate is larger than a mean free path of a sputtered particle.

16. The sputtering apparatus according to claim 15, wherein the distance between the target and the substrate is about 70 mm to about 150 mm.

17. A sputtering method utilizing a sputtering apparatus, comprising: a chamber, a plate disposed in the chamber with a substrate placed on the plate, a target facing the plate, a power supply unit coupled to the target, and a filter disposed between the substrate and the target, the sputtering method comprising:
disposing a target and a substrate inside the chamber in a manner that a distance between the target and the substrate is larger than a mean free path of a sputtered particle;
maintaining inner pressure of the chamber in a range of 0.01 Pa to 1 Pa by injecting discharge gas after a vacuum state is achieved inside the chamber; and
applying a voltage pulse to the target.

18. The sputtering method according to claim 17, further comprising heating a surface of the substrate with a heating unit after sputtering is completed.

19. The sputtering method according to claim 17, wherein the voltage pulse has a duty ratio in a range of 30% to 100%, and a pulse width of the voltage pulse is in a range of 30 ms to 100 ms.

20. The sputtering method according to claim 17, further comprising arranging the filter to have a polar angle of about 10 degrees to about 30 degrees from a normal line perpendicular to the center of the target.
